(19) United States
(12) Patent Application Publication
(10) Pub. No.: US 2023/0111396 A1
(43) Pub. Date: Apr. 13, 2023

(54) DISPLAY DEVICE

(71) Applicant: Samsung Display Co., LTD., Yongin-si (KR)

(72) Inventors: Hoon KIM, Yongin-si (KR); Won Tae KIM, Yongin-si (KR); Yong Sik HWANG, Yongin-si (KR)

(73) Assignee: Samsung Display Co., LTD., Yongin-si (KR)

(21) Appl. No.: 17/879,242

(22) Filed: Aug. 2, 2022

(30) Foreign Application Priority Data
Oct. 7, 2021 (KR) 10-2021-0133433

(51) Int. Cl. H01L 27/15; H01L 33/24; H01L 33/38; H01L 33/44; H01L 33/50

(52) U.S. Cl. CPC H01L 27/156; H01L 33/24; H01L 33/38; H01L 33/44; H01L 33/50

(57) ABSTRACT

A display device includes an emission area including light emitting elements; a line area including signal lines electrically connected to the light emitting elements; a transmission area disposed at a periphery of the emission area and the line area; a bank disposed in the emission area and the line area; and an optical layer disposed in a space surrounded by the bank in the transmission area.

### CROSS-REFERENCE TO RELATED APPLICATION(S)

The application claims priority to and benefits of Korean patent application No. 10-2021-0133433 under 35 U.S.C. § 119, filed in the Korean Intellectual Property Office on Oct. 7, 2021, the entire contents of which are incorporated herein by reference.

### BACKGROUND

### 1. Technical Field

The disclosure generally relates to a display device suitable for various specifications and capable of increasing transmittance thereof.

### 2. Description of the Related Art

The importance of display devices as communication media, has been emphasized because of the increasing research and developments of information technology.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device suitable for various specifications and capable of increasing transmittance thereof.

However, embodiments of the disclosure are not limited to those set forth herein. The above and other embodiments will become more apparent to one of ordinary skill in the art to which the disclosure pertains by referencing the detailed description of the disclosure given below.

In accordance with an aspect of the disclosure, there is provided a display device including: an emission area including light emitting elements; a line area including signal lines electrically connected to the light emitting elements; a transmission area disposed at a periphery of the emission area and the line area; a bank disposed in the emission area and the line area; and an optical layer disposed in a space surrounded by the bank in the transmission area.

The bank may include: a first overcoat layer; and a second overcoat layer disposed over the first overcoat layer.

The emission area may further include a color conversion layer disposed on the light emitting elements.

The first overcoat layer may be disposed over the color conversion layer.

The emission area may further include a color filter layer disposed on the color conversion layer.

The second overcoat layer may be disposed over the color filter layer.

The emission area may further include: a first electrode electrically connected to first end portions of the light emitting elements; and a second electrode electrically connected to second end portions of the light emitting elements.

A difference between a thickness of the bank and a thickness of the optical layer may be about 1 μm or less.

An area of the transmission area may be greater than at least one of an area of the emission area and an area of the line area.

The display device may further include a light transmissive film disposed on the optical layer.

In accordance with another aspect of the disclosure, there is provided a display device including a first line area extending in a first direction; a second line area extending in a second direction intersecting the first direction; an emission area electrically connected to the first line area or the second line area; a first bank disposed in the emission area and the first line area; a second bank disposed in the emission area and the second line area; and an optical layer disposed between the first bank and the second bank.

The first bank may extend in the first direction.

The second bank may extend in the second direction.

The first bank and the second bank may include a same material.

At least one of the first bank and the second bank may include an open area which is partially removed.

The optical layer may be disposed in the open area.

The optical layer may have a refractive index in a range of about 1.1 to about 1.3.

The optical layer may include a hollow particle.

A width of the first bank in the second direction may be greater than a width of the second bank in the first direction.

A thickness of the first bank may be greater than a thickness of the second bank.

### BRIEF DESCRIPTION OF THE DRAWINGS

An additional appreciation according to the embodiments of the disclosure will become more apparent by describing in detail the embodiments thereof with reference to the accompanying drawings, wherein:

FIGS. 1 and 2 are schematic perspective and cross-sectional views illustrating a light emitting element in accordance with an embodiment of the disclosure;

FIG. 3 is a schematic plan view illustrating a display device in accordance with an embodiment of the disclosure;

FIG. 4 is a schematic view of an equivalent circuit illustrating a sub-pixel in accordance with an embodiment of the disclosure;

FIG. 5 is a schematic plan view illustrating a display area in accordance with an embodiment of the disclosure;

FIG. 6 is a schematic cross-sectional view illustrating an emission area and a line area in accordance with an embodiment of the disclosure;

FIG. 7 is a schematic cross-sectional view taken along line A-A′ shown in FIG. 5;

FIG. 8 is a schematic cross-sectional view illustrating a light emitting layer and a circuit layer in accordance with an embodiment of the disclosure;

FIG. 9 is a schematic cross-sectional view illustrating a light emitting layer in accordance with another embodiment of the disclosure;

FIG. 10 is a schematic cross-sectional view illustrating an emission area and a transmission area in accordance with another embodiment of the disclosure; and

FIGS. 11 to 14 are schematic plan views illustrating a display area in accordance with still another embodiment of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

The effects and characteristics of the disclosure and a method of achieving the effects and characteristics will be clear by referring to the embodiments described below in detail together with the accompanying drawings. However, the disclosure is not limited to the embodiments disclosed herein but may be implemented in various forms. The embodiments are provided by way of example only so that a person of ordinary skilled in the art can fully understand the features in the present disclosure and the scope thereof. Therefore, the disclosure can be defined by the scope of the appended claims.

The terminology used herein is for the purpose of describing particular embodiments only and is not construed as limiting the disclosure. As used herein, the singular forms are intended to include the plural forms as well, unless the context clearly indicates otherwise. The terms “comprises/includes” and/or “comprising/including,” when used in this specification, specify the presence of mentioned component, step, operation and/or element, but do not exclude the presence or addition of one or more other components, steps, operations and/or elements.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

When described as that any element is “connected”, “coupled” or “accessed” to another element, it should be understood that it is possible that still another element may “connected”, “coupled” or “accessed” between the two elements as well as that the two elements are directly “connected”, “coupled” or “accessed” to each other.

The term “on” that is used to designate that an element or layer is on another element or layer includes both a case where an element or layer is located directly on another element or layer, and a case where an element or layer is located on another element or layer via still another element layer. Like reference numerals generally denote like elements throughout the specification.

It will be understood that, although the terms “first,” “second,” and the like may be used herein to describe various elements, these elements should not be limited by these terms. These terms are only used to distinguish one element from another element. Thus, a “first” element discussed below could also be termed a “second” element without departing from the teachings of the present disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, exemplary embodiments of the disclosure will be described in more detail with reference to the accompanying drawings.

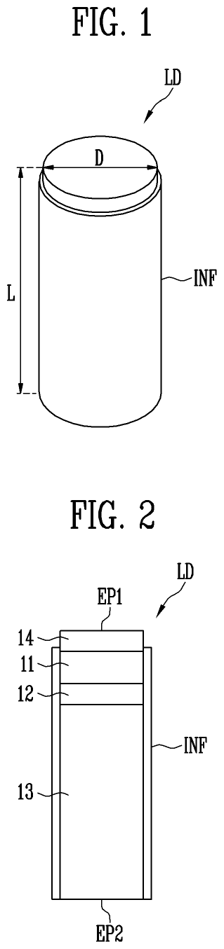

FIGS. 1 and 2 are schematic perspective and cross-sectional views illustrating a light emitting element in accordance with an embodiment of the disclosure. Although a pillar-shaped light emitting element LD is illustrated in FIGS. 1 and 2, the kind and/or shape of the light emitting element LD is not limited thereto.

Referring to FIGS. 1 and 2, the light emitting element LD may include a first semiconductor layer 11, an active layer 12, a second semiconductor layer 13, and/or an electrode layer 14.

The light emitting element LD may be provided in a pillar shape extending in one direction. The light emitting element LD may have a first end portion EP1 and a second end portion EP2. One of the first and second semiconductor layers 11 and 13 may be disposed at the first end portion EP1 of the light emitting element LD. Another of the first and second semiconductor layers 11 and 13 may be disposed at the second end portion EP2 of the light emitting element LD. For example, the first semiconductor layer 11 may be disposed at the first end portion EP1 of the light emitting element LD, and the second semiconductor layer 13 may be disposed at the second end portion EP2 of the light emitting element LD.

In some embodiments, the light emitting element LD may be a light emitting element manufactured in a pillar shape through an etching process, etc. In the specification, the term “pillar shape” may include a rod-like shape or a bar-like shape, of which an aspect ratio is greater than 1, such as a cylinder or a polyprism, and the shape of its cross-section is not limited thereto.

The light emitting element LD may have a size small to a degree of nanometer scale to micrometer scale. In an example, the light emitting element LD may have a diameter D (or width) in a range of nanometer scale to micrometer scale and/or a length L in a range of nanometer scale to micrometer scale. However, the size of the light emitting element LD is not limited thereto, and the size of the light emitting element LD may be variously changed according to design conditions of various types of devices (e.g., display device, or the like), which use a light emitting device using the light emitting element LD as a light source.

The first semiconductor layer 11 may be a first conductivity type semiconductor layer. For example, the first semiconductor layer 11 may include a p-type semiconductor layer. In an example, the first semiconductor layer 11 may include at least one semiconductor material of InAlGaN, GaN, AlGaN, InGaN, AlN, and InN, and include a p-type semiconductor layer doped with a first conductivity type dopant such as Mg. However, the material constituting the first semiconductor layer 11 is not limited thereto. The first semiconductor layer 11 may be configured with various materials.

The active layer 12 may be disposed between the first semiconductor layer 11 and the second semiconductor layer 13. The active layer 12 may include any one structure of a single well structure, a multi-well structure, a single quantum well structure, a multi-quantum well (MQW) structure, a quantum dot structure, and a quantum wire structure, but the disclosure is not limited thereto. The active layer 12 may include at least one of GaN, InGaN, InAlGaN, AlGaN, and AlN. However, the disclosure is not limited thereto. The active layer 12 may be configured with various materials.

In case that a voltage which is a threshold voltage or more is applied to ends (e.g., first end portion EP1 and second end portion EP2) of the light emitting element LD, electron-hole pairs may be combined in the active layer 12, and the light emitting element LD may emit light. The light emission of the light emitting element LD may be controlled by using such a principle (e.g., combination of electron-hole pairs), and the light emitting element LD may be used as a light source for various light emitting devices, including a pixel of a display device.

The second semiconductor layer 13 may be formed on the active layer 12, and include a semiconductor layer having a type different from that of the first semiconductor layer 11. For example, the second semiconductor layer 13 may include an n-type semiconductor layer. In an example, the second semiconductor layer 13 may include at least one semiconductor material of InAlGaN, GaN, AlGaN, InGaN, AlN, and InN, and include an n-type semiconductor layer doped with a second conductivity type dopant such as Si, Ge or Sn. However, the material constituting the second semiconductor layer 13 is not limited thereto. The second semiconductor layer 13 may be configured with various materials.

The electrode layer 14 may be disposed on the first end portion EP1 and/or the second end portion EP2 of the light emitting element LD. Although the electrode layer 14 of FIG. 2 is formed on the first semiconductor layer 11, the disclosure is not limited thereto. For example, a separate electrode layer may be further disposed on the second semiconductor layer 13.

The electrode layer 14 may include a transparent metal or a transparent metal oxide. In an example, the electrode layer 14 may include at least one of indium tin oxide (ITO), indium zinc oxide (IZO), zinc oxide (ZnO), and zinc tin oxide (ZTO), but the disclosure is not limited thereto. In case that the electrode layer 14 may be made of a transparent metal or a transparent metal oxide, light generated in the active layer 12 of the light emitting element LD may pass through the electrode layer 14 and be emitted to the outside of the light emitting element LD.

An insulative film INF may be provided on a surface of the light emitting element LD. The insulative film INF may be disposed (e.g., directly disposed) on surfaces of the first semiconductor layer 11, the active layer 12, the second semiconductor layer 13, and/or the electrode layer 14. The insulative film INF may expose the first and second end portions EP1 and EP2 of the light emitting element LD, which have different polarities from each other. In some embodiments, the insulative film INF may expose a side portion of the electrode layer 14 and/or the second semiconductor layer 13, which is adjacent to the first and second end portions EP1 and EP2 of the light emitting element LD.

The insulative film INF may prevent an electrical short circuit which may occur in case that the active layer 12 contacts a conductive material except the first and second semiconductor layers 11 and 13. For example, the insulative film INF may electrically insulate the active layer 12 from other elements outside of the light emitting element LD. The insulative film INF may minimize a surface defect of the light emitting elements LD. Thus, the lifetime (or lifespan) and light emission efficiency of the light emitting elements LD may be improved.

The insulative film INF may include at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). For example, the insulative film INF may be configured as a double layer, and layers constituting the double layer may include different materials. In an example, the insulative film INF may be configured as a double layer including aluminum oxide (AlOₓ) and silicon oxide (SiOₓ), but the disclosure is not limited thereto. In some embodiments, the insulative film INF may be omitted.

A light emitting device including the above-described light emitting element LD may be used in various kinds of devices (e.g., display devices) which require a light source. For example, multiple light emitting elements LD may be disposed in each pixel of the display panel, and used as a light source of each pixel. However, the application field (or usage) of the light emitting element LD is not limited to the above-described example. For example, the light emitting element LD may be used in other types of devices that require the light source, such as a lighting device.

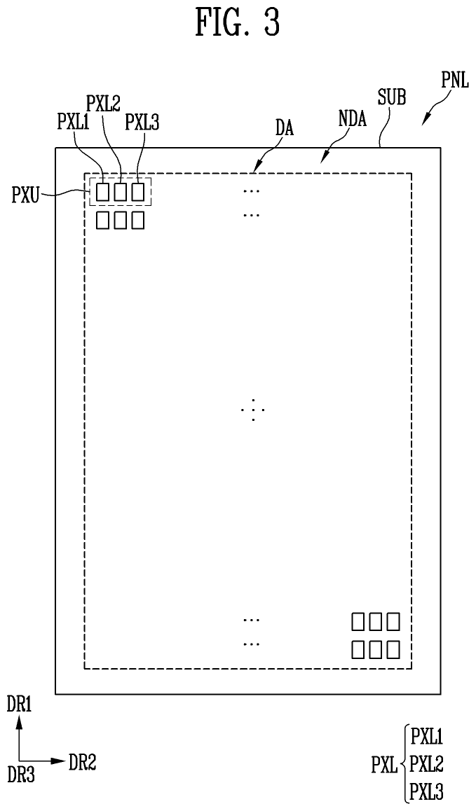

FIG. 3 is a schematic plan view illustrating a display device in accordance with an embodiment of the disclosure.

In FIG. 3, description of a display device (e.g., display panel PNL provided in display device) is provided as an example of an electronic device which uses the light emitting element LD described in the embodiment shown in FIGS. 1 and 2 as a light source.

For convenience of description, description of a display area DA of the display panel PNL is provided with reference to FIG. 3. However, in some embodiments, at least one driving circuit (e.g., at least one of a scan driver and a data driver), lines, and/or pads, which are not shown in the drawing, may be further disposed in the display panel PNL.

Referring to FIG. 3, the display panel PNL and a substrate SUB for forming the display panel PNL may include the display area DA for displaying an image and a non-display area NDA except the display area DA. The display area DA may constitute a screen on which the image is displayed, and the non-display area NDA may be another area of the display panel PNL except the display area DA.

A pixel part PXU may be disposed in the display area DA. The pixel part PXU may include a first sub-pixel PXL1, a second sub-pixel PXL2, and/or a third sub-pixel PXL3. Hereinafter, in case that at least one sub-pixel of the first sub-pixel PXL1, the second sub-pixel PXL2, and the third sub-pixel PXL3 is arbitrarily designated or in case that two or more kinds of sub-pixels of the first sub-pixel PXL1, the second sub-pixel PXL2, and the third sub-pixel PXL3 are inclusively designated, the corresponding sub-pixel or the corresponding sub-pixels are referred to as a “sub-pixel PXL” or “sub-pixels PXL.”

The sub-pixels PXL may be arranged (e.g., regularly arranged) in the display area DA according to a stripe structure, a PENTILE™ structure, or the like. However, the arrangement structure of the sub-pixels PXL is not limited thereto, and the sub-pixels PXL may be arranged in the display area DA by using various structures and/or methods.

In some embodiments, two or more kinds of the sub-pixels PXL emitting lights of different colors from each other. In an example, multiple first sub-pixels PXL1 emitting light of a first color, multiple second sub-pixels PXL2 emitting light of a second color, and multiple third sub-pixels PXL3 emitting light of a third color may be arranged in the display area DA. At least one first sub-pixel PXL1, a least one second sub-pixel PXL2, and at least one third sub-pixel PXL3, which are disposed adjacent to each other, may constitute one pixel part PXU capable of emitting lights of various colors. For example, each of the first to third sub-pixels PXL1, PXL2, and PXL3 may be a sub-pixel emitting light of a color. In some embodiments, the first sub-pixel PXL1 may be a red pixel emitting red light, the second sub-pixel PXL2 may be a green pixel emitting green light, and the third sub-pixel PXL3 may be a blue pixel emitting blue light. However, the disclosure is not limited thereto.

In an embodiment, the first sub-pixel PXL1, the second sub-pixel PXL2, and the third sub-pixel PXL3 may have light emitting elements emitting light of a same color, and may include color conversion layers and/or color filters of different colors from each other, which are disposed on the respective light emitting elements. Thus, the first sub-pixel PXL1, the second sub-pixel PXL2, and the third sub-pixel PXL3 may respectively emit lights of the first color, the second color, and the third color. In another embodiment, the first sub-pixel PXL1, the second sub-pixel PXL2, and the third sub-pixel PXL3 may respectively have a light emitting element of the first color, a light emitting element of the second color, and a light emitting element of the third color as light sources. Thus, the light emitting elements may respectively emit lights of the first color, the second color, and the third color. However, the color, kind, and/or number of the sub-pixels PXL constituting each pixel part PXU are not limited thereto. In an example, the color of light emitted by each sub-pixel PXL may be variously changed.

The sub-pixel PXL may include at least one light source driven by a control signal (e.g., a scan signal and a data signal) and/or a power source (e.g., a first power source and a second power source). In an embodiment, the light source may include at least one light emitting element LD in accordance with the embodiment shown in FIGS. 1 and 2. For example, the light source may include a subminiature pillar-shaped light emitting element LD having a size small to a degree of nanometer scale to micrometer scale. However, the disclosure is not limited thereto. Various types of light emitting elements LD may be used as the light source of the sub-pixel PXL.

In an embodiment, each sub-pixel PXL may be configured as an active pixel. However, the kind, structure, and/or driving method of sub-pixels PXL which may be applied to the display device are not limited thereto. For example, each sub-pixel PXL may be configured as a pixel of a passive or active light emitting display device using various structures and/or driving methods.

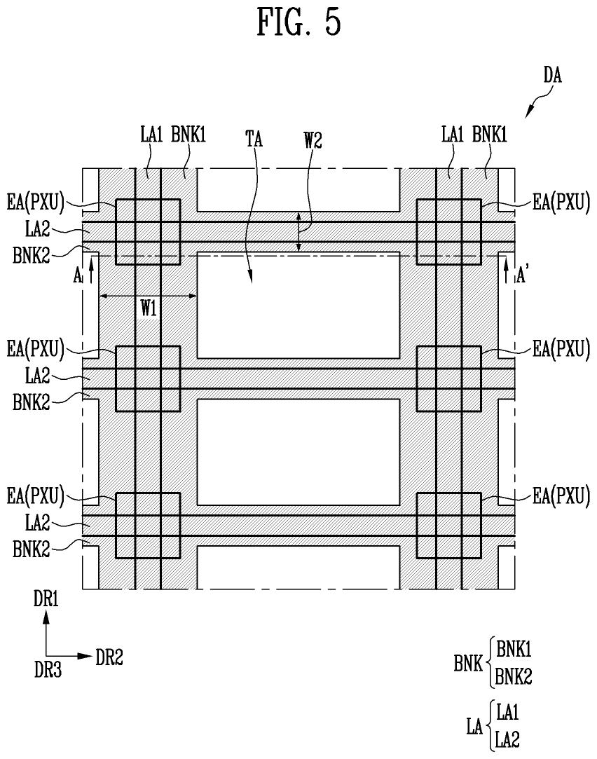

In an embodiment, the display panel PNL may include transmission areas TA (e.g., refer to FIG. 5) disposed in the display area DA. The transmission area TA (e.g., refer to FIG. 5) may serve as or be implemented with, for example, a transmission window which is disposed at a periphery of the sub-pixels PXL, and an object or background located at one side of the display panel PNL may be viewed by a user at another side of the display panel PNL. The user can view necessary information through the display panel PNL while viewing an object or background located at the rear of the display panel PNL. For example, a transparent display device may be implemented by using the transmission area TA, and thus spatial and temporal limitations of the existing display device may be resolved. Description of the transmission area TA is provided below in detail later with reference to FIG. 5.

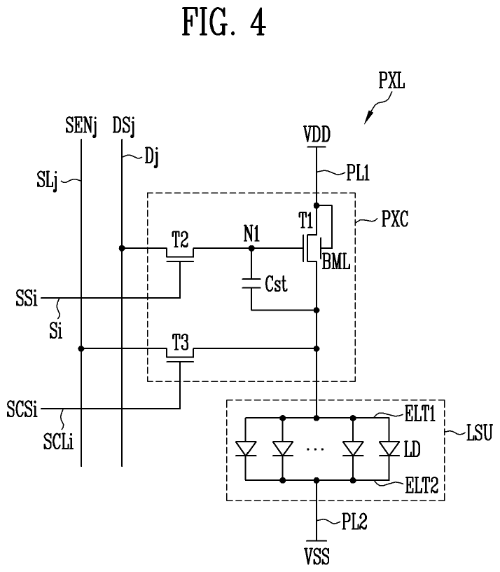

FIG. 4 is a schematic view of an equivalent circuit illustrating a sub-pixel in accordance with an embodiment of the disclosure.

Referring to FIG. 4, the sub-pixel PXL may include a light emitting part LSU and a pixel circuit PXC. The light emitting part LSU may generate light with a luminance corresponding to a data signal, and the pixel circuit PXC may drive the light emitting part LSU.

The light emitting part LSU may include at least one light emitting element LD electrically connected between a first power source VDD and a second power source VSS. For example, the light emitting element LSU may include a first electrode ELT1, a second electrode ELT2, and light emitting elements LD. The first electrode ELT1 may be electrically connected to the first power source VDD via the pixel circuit PXC and a first power line PL1. The second electrode ELT2 may be electrically connected to the second power source VSS through a second power line PL2. The light emitting elements LD may be electrically connected between the first and second electrodes ELT1 and ELT2. In an embodiment, the first electrode ELT1 may be an anode electrode, and the second electrode ELT2 may be a cathode electrode.

Each of the light emitting elements LD may include a first end portion electrically connected to the first power source VDD through the first electrode ELT1 and/or the pixel circuit PXC and a second end portion electrically connected to the second power source VSS through the second electrode ELT2. For example, the light emitting elements LD may be electrically connected in a forward direction between the first and second electrodes ELT1 and ELT2. The light emitting elements LD electrically connected (e.g., connected in series) in the forward direction between the first power source VDD and the second power source VSS may respectively form effective light sources, and the effective light sources may constitute the light emitting part LSU of the sub-pixel PXL.

The first power source VDD and the second power source VSS may have different potentials from each other, and the light emitting elements LD may emit light. In an example, the first power source VDD may be set as a high-potential power source, and the second power source VSS may be set as a low-potential power source. A potential difference between the first power source VDD and the second power source VSS may be equal to or higher than a threshold voltage of the light emitting elements LD during at least an emission period of the sub-pixel PXL.

One end portions of the light emitting elements LD constituting each light emitting element LSU may be commonly connected to the pixel circuit PXC through one electrode (e.g., first electrode ELT1 of each sub-pixel PXL) of the light emitting element LSU, and be electrically connected to the first power source VDD through the pixel circuit PXC and the first power line PL1. The other end portions of the light emitting elements LD may be commonly connected to the second power source VSS through another electrode (e.g., second electrode ELT2 of each sub-pixel PXL) of the light emitting element LSU and the second power line PL2.

The light emitting elements LD may emit light with a luminance corresponding to a driving current supplied through a corresponding pixel circuit PXC. For example, the pixel circuit PXC may supply a driving current to the light emitting part LSU during each frame period, and the driving current supplied by the pixel circuit PXC may correspond to a grayscale value to be expressed in a corresponding frame. The driving current supplied to the light emitting part LSU may be divided into the light emitting elements LD, and flow through the light emitting elements LD connected (e.g., connected in series) in the forward direction. Accordingly, the light emitting part LSU may emit the light with the luminance corresponding to the driving current, and each light emitting element LD may emit light with a luminance corresponding to a current (e.g., divided current) flowing therethrough.

The pixel circuit PXC may be electrically connected between the first power source VDD and the first electrode ELT1. The pixel circuit PXC may be electrically connected to a scan line Si (e.g., ith scan line Si) and a data line Dj (e.g., jth data line Dj) of a corresponding sub-pixel PXL. In an example, in case that the sub-pixel PXL is disposed on an ith (i is a natural number) horizontal line (or row) and a jth (j is a natural number) vertical line (or column) of the display area DA, the pixel circuit PXC may be electrically connected to the ith scan line Si and the jth data line Dj.

In some embodiments, the pixel circuit PXC may include transistors T1, T2, and T3 and at least one storage capacitor Cst.

A first transistor T1 may be electrically connected between the first power source VDD and the light emitting part LSU. For example, a first electrode (e.g., drain electrode) of the first transistor T1 may be electrically connected to the first power source VDD, and a second electrode (e.g., source electrode) of the first transistor T1 may be electrically connected to first electrode ELT1. A gate electrode of the first transistor T1 may be electrically connected to a first node N1. The first transistor T1 may control a driving current supplied to the light emitting part LSU, corresponding to a voltage of the first node N1. For example, the first transistor T1 may control the driving current based on (or in response to) the voltage of the first node N1. For example, the first transistor T1 may be a driving transistor for controlling the driving current of the sub-pixel PXL.

In an embodiment, the first transistor T1 may further include a lower conductive layer BML. The lower conductive layer BML, may be referred to as a “lower electrode,” a “back gate electrode,” or a “lower light blocking layer”. The gate electrode and the lower conductive layer BML of the first transistor T1 may overlap each other in a plan view, and an insulating layer may be interposed therebetween. In an embodiment, the lower conductive layer BML may be electrically connected to one electrode (e.g., a source electrode or drain electrode) of the first transistor T1.

In case that the first transistor T1 includes the lower conductive layer BML, a back-biasing technique (or sync technique) may be applied. In the back-biasing technique (or sync technique), a back-biasing voltage may be applied to the lower conductive layer BML of the first transistor T1 in driving of the sub-pixel PXL to move a threshold voltage of the first transistor T1 in a negative direction or positive direction. In an example, a source-sync technique electrically connecting the lower conductive layer BML to a source electrode of the first transistor T1 may be applied, and the threshold voltage of the first transistor T1 may be moved in the negative direction or positive direction. In case that the lower conductive layer BML is disposed on the bottom of a semiconductor pattern constituting a channel of the first transistor T1, the lower conductive layer BML may serve as or be implemented with, for example, a light blocking pattern. Thus, operational characteristics of the first transistor T1 may be stabilized. However, the function and/or application method of the lower conductive layer BML are/is not limited thereto.

A second transistor T2 may be electrically connected between the data line Dj and the first node N1. For example, a first electrode of the second transistor T2 may be electrically connected to the data line Dj, and a second electrode of the second transistor T2 may be electrically connected to the first node N1. A gate electrode of the second transistor T2 may be electrically connected to the scan line Si. The second transistor T2 may be turned on to electrically connect the date line Dj and the first node N1 to each other in case that a scan signal SSi having a gate-on voltage (e.g., high level voltage) is supplied from the scan line Si.

A data signal DSj of the corresponding frame may be supplied to the data line Dj in each frame period. The data signal DSj may be transferred to the first node N1 through the second transistor T2 turned on during a period in which the scan signal SSi having the gate-on voltage is supplied. For example, the second transistor T2 may be a switching transistor for transferring each data signal DSj to the inside of the sub-pixel PXL.

A third transistor T3 may be electrically connected between the first transistor T1 and a sensing line SLj. For example, one electrode of the third transistor T3 may be electrically connected to the second electrode (e.g., source electrode) of the first transistor T1, which is electrically connected to the first electrode ELT1, and another electrode of the third transistor T3 may be electrically connected to the sensing line SLj. In case that the sensing line SLj is omitted, the another electrode of the third transistor T3 may be electrically connected to the data line Dj.

A gate electrode of the third transistor T3 may be electrically connected to a sensing control line SCLi. In case that the sensing control line SCLi is omitted, the gate electrode of the third transistor T3 may be electrically connected to the scan line Si. The third transistor T3 may be turned on by a sensing control signal SCSi having a gate-on voltage (e.g., high level voltage), which is supplied to the sensing control line SCLi during a sensing period. Thus, the third transistor T3 may electrically connect the sensing line SLj and the first transistor T1 to each other.

In some embodiments, the sensing period may be a period for extracting a characteristic (e.g., a threshold voltage of the first transistor T1, or the like) of each of the sub-pixels PXL disposed in the display area DA. During the sensing period, a reference voltage at which the first transistor T1 can be turned on may be supplied to the first node N1 through the data line Dj and the second transistor T2, or the first transistor T1 may be turned on as each sub-pixel PXL is electrically connected to a current source or the like. In addition, the first transistor T1 may be electrically connected to the sensing line SLj as the third transistor T3 is turned on by supplying the sensing control signal SCSi having the gate-on voltage to the third transistor T3. Subsequently, a sensing signal SENj may be acquired through the sensing line SLj, and a characteristic (e.g., threshold voltage of first transistor T1 or the like) of each sub-pixel PXL may be detected by using the sensing signal SENj. A characteristic deviation between the sub-pixels PXL disposed in the display area DA may be compensated, and information on the characteristic of each sub-pixel PXL may be used to convert image data (e.g., image data without deviation between sub-pixels PXL).

One electrode of the storage capacitor Cst may be electrically connected to the second electrode of the first transistor T1, and another electrode of the storage capacitor Cst may be electrically connected to the first node N1. The storage capacitor Cst may charge a voltage corresponding to the data signal DSj supplied to the first node N1 during each frame period.

Although an embodiment in which the effective light sources (i.e., the light emitting elements LD) constituting each light emitting element LSU are all electrically connected in parallel has been illustrated in FIG. 4, the disclosure is not limited thereto. For example, the light emitting part LSU of each sub-pixel PXL may be configured to include at least two-stage serial structure. Light emitting elements constituting each serial stage may be electrically connected in series to each other by at least one intermediate electrode.

Although the transistors included in the pixel circuit PXC of FIG. 4 are all n-type transistors, the disclosure is not limited thereto. For example, at least one of the first to third transistors T1, T2, and T3 may be changed to a P-type transistor.

The structure and driving method of the sub-pixel PXL may be variously modified. For example, the pixel circuit PXC may be configured as pixel circuit using various structures and/or various driving methods, in addition to the embodiment shown in FIG. 4.

FIG. 5 is a schematic plan view illustrating a display area in accordance with an embodiment of the disclosure.

Referring to FIG. 5, an emission area EA, a line area LA, and a transmission area TA may be disposed in the display area DA.

The emission area EA may include a pixel part PXU including the above-described light emitting elements LD (e.g., refer to FIG. 4). The emission area EA may be electrically connected to the line area LA. In an example, the line area LA may include signal lines (e.g., a power line, a data line, a scan line, or the like), which constitute the pixel circuit PXC (e.g., refer to FIG. 4) for driving the emission area EA.

The line area LA may include a first line area LA1 and a second line area LA2, which extend in different directions from each other. The first line area LA1 may extend in a first direction DR1. The second line area LA2 may extend in a second direction DR2 intersecting the first direction DR. The first line area LA1 and the second line area LA2 may intersect each other, and be electrically connected to an emission area EA disposed on a corresponding row or a corresponding column.

A bank BNK may be disposed in the emission area EA and/or the line area LA. In an example, the bank BNK may overlap the emission area EA and/or the line area LA in a plan view. The bank BNK may include a first bank BNK1 and a second bank BNK2, which extend in different directions from each other. The first bank BNK1 may extend in the first direction DR1, and the second bank BNK2 may extend in the second direction DR2.

The first bank BNK1 may be disposed on the emission area EA and/or the first line area LA1. The first bank BNK1 may cover (overlap, e.g., in a plan view) the emission area EA and/or the first line area LA1. For example, the first bank BNK1 may overlap (e.g., completely overlap) the emission area EA and/or the first line area LA1, e.g., in a plan view, but the disclosure is not limited thereto.

The second bank BNK2 may be disposed on the emission area EA and/or the second line area LA2. The second bank BNK2 may cover the emission area EA and/or the second line area LA2. For example, the second bank BNK2 may overlap (e.g., completely overlap) the emission area EA and/or the second line area LA2 in a plan view, but the disclosure is not limited thereto.

A width W1 of the first bank BNK1 in the second direction DR2 may be different from a width W2 of the second bank BNK2 in the first direction DR1. In an example, the width W1 of the first bank BNK1 in the second direction DR2 may be greater than the width W2 of the second bank BNK2 in the first direction DR1, but the disclosure is not limited thereto.

The transmission area TA may be disposed at a periphery of the emission area EA and/or the line area LA. The transmission area TA may not overlap the emission area EA and/or the line area LA in a plan view. Accordingly, the transmission area TA may serve as or be implemented with, for example, a transmission window through which an object or background located at a side of the display panel PNL (e.g., refer to FIG. 3) may be viewed by a user at another side of the display panel PNL (e.g., refer to FIG. 3). Thus, a transparent display device may be readily implemented. In an example, the transparent display device may have a transmittance (e.g., light transmittance) of about 60% or more, and an area occupied by the transmission area TA in the display area DA may be about 70% or more. Thus, the transparent display device may satisfy the transmittance (e.g., light transmittance) of about 60%. For example, an area of the transmittance area TA may be greater than that of the emission area EA and/or that of the line area LA. However, the disclosure is not limited thereto, and the area of the transmission area TA may be variously changed within a range in which the transmittance (e.g., light transmittance) of the transparent display device may be secured.

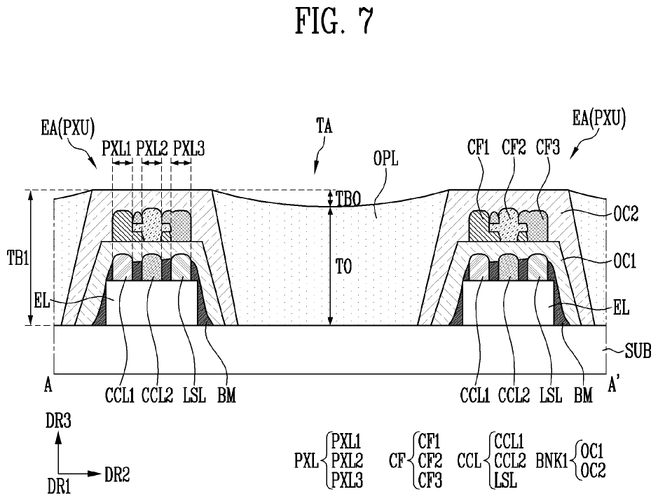

In an embodiment, an optical layer OPL (e.g., refer to FIG. 7) may be disposed in the transmission area TA to improve the transmittance (e.g., light transmittance) of the transmission area TA. In case that the optical layer OPL (e.g., refer to FIG. 7) is disposed in the transmission area TA, the transmittance (e.g., light transmittance) of the transmission area TA may be improved, and a step difference caused by the emission area EA and/or the line area LA may be minimized. Detailed description of the above is provided with reference to FIG. 7.

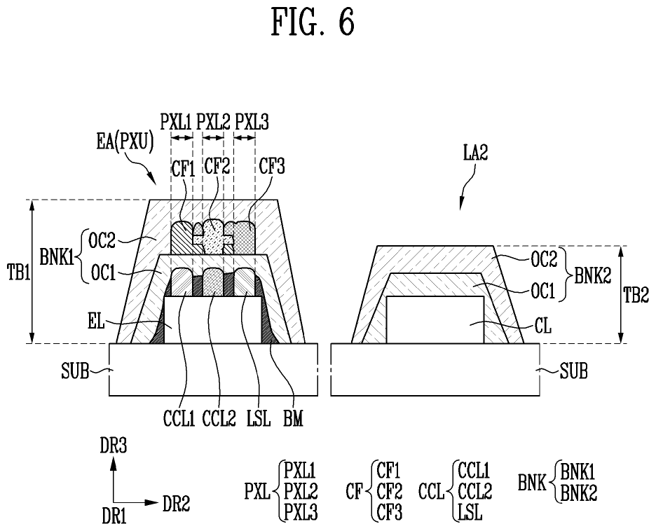

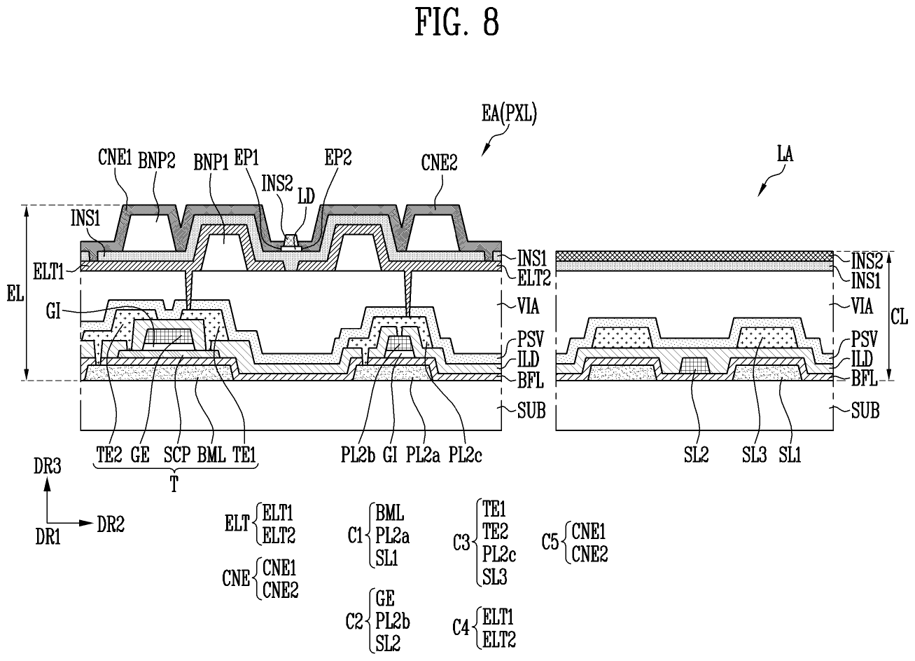

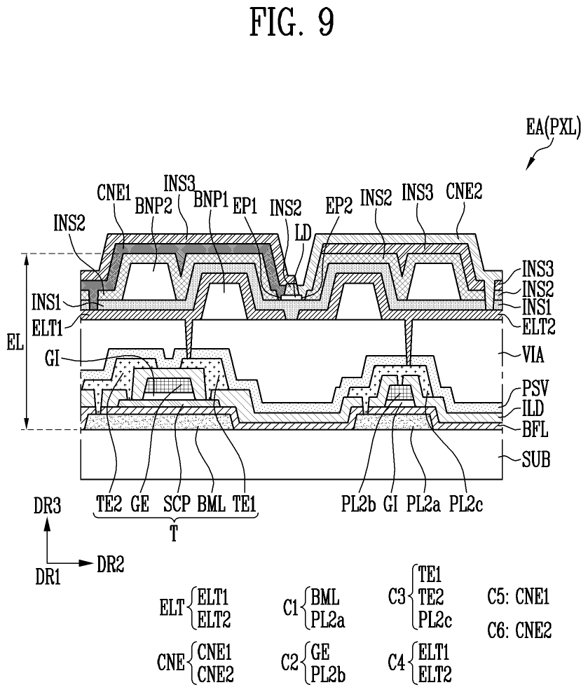

FIG. 6 is a schematic cross-sectional view illustrating an emission area and a line area in accordance with an embodiment of the disclosure. FIG. 7 is a schematic cross-sectional view taken along line A-A′ shown in FIG. 5. FIG. 8 is a schematic cross-sectional view illustrating a light emitting layer and a circuit layer in accordance with an embodiment of the disclosure. FIG. 9 is a schematic cross-sectional view illustrating a light emitting layer in accordance with another embodiment of the disclosure.

Referring to FIG. 6, a light emitting element EL, a color conversion layer CCL, a color filter layer CF, and/or a first bank BNK1 may be disposed in the emission area EA.

The light emitting layer EL may be disposed on a substrate SUB, and include the above-described light emitting elements LD (e.g., refer to FIG. 4). A detailed configuration of the light emitting layer EL is provided below with reference to FIG. 8.

The substrate SUB may constitute a base member, and may be a rigid or flexible substrate or a film. In an example, the substrate SUB may be a rigid substrate made of glass or tempered glass, a flexible substrate (or thin film) made of a plastic or metallic material, or at least one insulating layer. The material and/or property of the substrate SUB is not limited thereto. In an embodiment, the substrate SUB may be substantially transparent. The term “substantially transparent” may mean that light may be transmitted with a transmittance (e.g., light transmittance) or more. In another embodiment, the substrate SUB may be translucent or opaque. The substrate SUB may include a reflective material in some embodiments.

The color conversion layer CCL may be disposed on the light emitting layer EL. The color conversion layer CCL may be disposed on the light emitting layer EL including the light emitting elements LD (e.g., refer to FIG. 4).

The color conversion layer CCL may include a first color conversion layer CCL1 disposed in a first sub-pixel PXL1, a second color conversion layer CCL2 disposed in a second sub-pixel PXL2, and a light scattering layer LSL disposed in a third sub-pixel PXL3.

In an embodiment, the first to third sub-pixels PXL1, PXL2, and PXL3 may include light emitting elements LD (e.g., refer to FIG. 4) emitting light of a same color. For example, the first to third sub-pixels PXL1, PXL2, and PXL3 may include light emitting elements LD (e.g., refer to FIG. 4) emitting light of a third color (or blue). The color conversion layer CCL including color conversion particles may be disposed on each of the first to third sub-pixels PXL1, PXL2, and PXL3, and a full-color image may be displayed.

The first color conversion layer CCL1 may include first color conversion particles for converting light of the third color, which is emitted from the light emitting element LD (e.g., refer to FIG. 4), into light of a first color. For example, the first color conversion layer CCL1 may include first quantum dots QD1 dispersed in a matrix material such as base resin.

In an embodiment, in case that the light emitting element LD (e.g., refer to FIG. 4) is a blue light emitting element emitting blue light, and the first sub-pixel PXL1 may be a red pixel. The first color conversion layer CCL1 may include a first quantum dot QD1 for converting the blue light, which is emitted from the blue light emitting element, into red light. The first quantum dot QD1 may shift a wavelength of the blue light according to energy transition. For example, the first quantum dot QD1 may absorb the blue light and emit the red light. In case that the first sub-pixel PXL1 is a pixel of another color, the first color conversion layer CCL1 may include a first quantum dot QD1 corresponding to the color of the first sub-pixel PXL1.

The second color conversion layer CCL2 may include second color conversion particles for converting light of the third color, which is emitted from the light emitting element LD (e.g., refer to FIG. 4), into light of a second color. For example, the second color conversion layer CCL2 may include second quantum dots QD2 dispersed in a matrix material such as base resin.

In an embodiment, in case that the light emitting element LD (e.g., refer to FIG. 4) is the blue light emitting element emitting the blue light, and the second sub-pixel PXL2 may be a green pixel. The second color conversion layer CCL2 may include a second quantum dot QD2 for converting the blue light, which is emitted from the blue light emitting element, into green light. The second quantum dot QD2 may shift a wavelength of the blue light according to energy transition. For example, the second quantum dot QD2 may absorb the blue light and emit the green light. In case that the second sub-pixel PXL2 is a pixel of another color, the second color conversion layer CCL2 may include a second quantum dot QD2 corresponding to the color of the second sub-pixel PXL2.

In an embodiment, the blue light having a relatively short wavelength in a visible light band may be incident into the first quantum dot QD1 and the second quantum dot QD2, and absorption coefficients of the first quantum dot QD1 and the second quantum dot QD2 may be increased. Accordingly, the efficiency of light emitted (e.g., finally emitted) from the first sub-pixel PXL1 and the second sub-pixel PXL2 may be improved, and excellent color reproduction may be ensured. The light emitting part LSU (e.g., refer to FIG. 4) of each of the first to third sub-pixels PXL1, PXL2, and PXL3 may be configured by using the light emitting elements LD (e.g., refer to FIG. 4) of a same color (e.g., blue light emitting elements), and the manufacturing efficiency of the display device may be improved.

The light scattering layer LSL may be provided to efficiently use light of the third color (or blue) emitted from the light emitting element LD (e.g., refer to FIG. 4). In an example, in case that the light emitting element LD is the blue light emitting element emitting the blue light, and the third sub-pixel PXL3 is a blue pixel, the light scattering layer LSL may include at least one kind of light scattering particles SCT to efficiently use the light emitted from the light emitting element LD.

For example, the light scattering layer LSL may include light scattering particles SCT dispersed in a matrix material such as base resin. In an example, the light scattering layer LSL may include a light scattering particle SCT such as silica, but the material constituting the light scattering particles SCT is not limited thereto. In other embodiments, the light scattering particles SCT may not be disposed in only the third sub-pixel PXL3, and may be selectively included even at the inside of the first color conversion layer CCL1 or the second color conversion layer CCL2. In some embodiments, the light scattering particle may be omitted, and the light scattering layer LSL configured with transparent polymer may be provided.

A light blocking layer BM may be further disposed on at least one of the first color conversion layer CCL1, the second color conversion layer CCL2, and the light scattering layer LSL. The light blocking layer BM may be disposed at a boundary of the first to third sub-pixels PXL1, PXL2, and PXL3. The material of the light blocking layer BM is not limited thereto, and may be configured with various light blocking materials.

A first overcoat layer OC1 of the first bank BNK1 may be disposed over the color conversion layer CCL. The first overcoat layer OC1 of the first bank BNK1 may cover a lower member including the color conversion layer CCL. The first overcoat layer OC1 of the first bank BNK1 may planarize a step difference of the color conversion layer CCL. The first overcoat layer OC1 of the first bank BNK1 may be provided throughout the first to third sub-pixels PXL1, PXL2, and PXL3.

The first overcoat layer OC1 of the first bank BNK1 may include at least one organic material of acrylic resin, epoxy resin, phenolic resin, polyamides resin, polyimides resin, unsaturated polyesters resin, poly-phenylene ethers resin, poly-phenylene sulfides resin, and benzocyclobutene (BCB). However, the disclosure is not limited thereto, and the first overcoat layer OC1 of the first bank BNK1 may include various kinds of inorganic insulating materials, including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The color filter layer CF may be disposed on the first overcoat layer OC1 of the first bank BNK1. The color filter layer CF may include color filters CF1, CF2, and CF3 which accord with (or correspond to) colors of sub-pixels PXL, respectively. The color filters CF1, CF2, and CF3 which accord with (or correspond to) the colors of the first to third sub-pixels PXL1, PXL2, and PXL3 may be disposed (e.g., disposed on the first overcoat layer OC1), and a full-color image may be displayed.

The color filter layer CF may include a first color filter CF1, a second color filter CF2, and a third color filter CF3. The first color filter CF1 may be disposed in the first sub-pixel PXL1, and may selectively transmit the light emitted from the first sub-pixel PXL1. The second color filter CF2 may be disposed in the second sub-pixel PXL2, and may selectively transmit the light emitted from the second sub-pixel PXL2. The third color filter CF3 may be disposed in the third sub-pixel PXL3, and may selectively transmit the light emitted from the third sub-pixel PXL3.

In an embodiment, the first color filter CF1, the second color filter CF2, and the third color filter CF3 may be respectively a red color filter, a green color filter, and a blue color filter, but the disclosure is not limited thereto. Hereinafter, in case that an arbitrary color filter (or at least one color filter) of the first color filter CF1, the second color filter CF2, and the third color filter CF3 is designated or in case that two or more kinds of color filters of the first color filter CF1, the second color filter CF2, and the third color filter CF3 are inclusively designated, the corresponding color filter or the corresponding color filters may be referred to as a “color filter CF” or “color filters CF.”

The first color filter CF1 may overlap the light emitting layer EL (or light emitting element LD of FIG. 4) and the first color conversion layer CCL of the first sub-pixel PXL1 in a third direction DR3. The first color filter CF1 may include a color filter material for selectively transmitting light of the first color (or red). For example, in case that the first sub-pixel PXL1 is the red pixel, the first color filter CF1 may include a red color filter material.

The second color filter CF2 may overlap the light emitting layer EL (or the light emitting element LD of FIG. 4) and the second color conversion layer CCL of the second sub-pixel PXL2 in the third direction DR3. The second color filter CF2 may include a color filter material for selectively transmitting light of a second color (or green). For example, in case that the second sub-pixel PXL2 is the green pixel, the second color filter CF2 may include a green color filter material.

The third color filter CF3 may overlap the light emitting layer EL (or light emitting element LD of FIG. 4) and the light scattering layer LSL of the third sub-pixel PXL3 in the third direction DR3. The third color filter CF3 may include a color filter material for selectively transmitting light of a third color (or blue). For example, in case that the third sub-pixel PXL3 is a blue pixel, the third color filter CF3 may include a blue color filter material.

The first to third color filters CF1, CF2, and CF3 may overlap each other at the boundary of the first to third sub-pixels PXL1, PXL2, and PXL3 in a plan view. The first to third color filters CF1, CF2, and CF3 may overlap each other in a plan view. Thus, a color mixture defect viewed at a front or side of the display device may be prevented. However, the disclosure is not limited thereto, and a light blocking layer for preventing the color mixture defect may be additionally disposed at the boundary of the first to third sub-pixels PXL1, PXL2, and PXL3.

A second overcoat layer OC2 of the first bank BNK1 may be disposed over the color filter layer CF. The second overcoat layer OC2 of the first bank BNK1 may be provided throughout the first to third sub-pixels PXL1, PXL2, and PXL3. The second overcoat layer OC2 of the first bank BNK1 may cover a lower member including the color filter layer CF. The second overcoat layer OC2 of the first bank BNK1 may prevent moisture or air from infiltrating into the above-described lower member (e.g., light emitting layer EL, color conversion layer CCL, sub-pixels PXL, or the like). The second overcoat layer OC2 of the first bank BNK1 may protect the above-described lower member from a foreign matter such as dust.

The second overcoat layer OC2 of the first bank BNK1 may include at least one organic material of acrylic resin, epoxy resin, phenolic resin, polyamides resin, polyimides resin, unsaturated polyesters resin, poly-phenylene ethers resin, poly-phenylene sulfides resin, and benzocyclobutene (BCB). However, the disclosure is not limited thereto, and the second overcoat layer OC2 of the first bank BNK1 may include various kinds of inorganic insulating materials, including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). In an example, the second overcoat layer OC2 of the first bank BNK1 may include a same material as the first overcoat layer OC1 of the first bank BNK1, but the disclosure is not limited thereto.

A circuit layer CL and/or a second bank BNK2 may be disposed in the second line part L2A.

The circuit layer CL may be disposed on the substrate SUB, and include signal lines constituting the above-described pixel circuit PXC (e.g., refer to FIG. 4). A detailed configuration of the circuit layer CL is provided below with reference to FIG. 8.

The second bank BNK2 may be disposed over the circuit layer CL. The second bank BNK2 may include a first overcoat layer OC1 and a second overcoat layer OC2.

The first overcoat layer OC1 of the second bank BNK2 may cover the circuit layer CL. The first overcoat layer OC1 of the second bank BNK2 may include at least one organic material of acrylic resin, epoxy resin, phenolic resin, polyamides resin, polyimides resin, unsaturated polyesters resin, poly-phenylene ethers resin, poly-phenylene sulfides resin, and benzocyclobutene (BCB). However, the disclosure is not limited thereto, and the first overcoat layer OC1 of the second bank BNK2 may include various kinds of inorganic insulating materials, including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

In some embodiments, the first overcoat layers OC1 of the first bank BNK1 and the second bank BNK2 may be formed of a same material. In an example, the first overcoat layers OC1 of the first bank BNK1 and the second bank BNK2 may be simultaneously formed through a same process, but the disclosure is not limited thereto.

The second overcoat layer OC2 of the second bank BNK2 may be disposed over the first overcoat layer OC1 of the second bank BNK2. The second overcoat layer OC2 of the second bank BNK2 may be disposed (e.g., directly disposed) over the first overcoat layer OC1 of the second bank BNK2.

The second overcoat layer OC2 of the second bank BNK2 may include at least one organic material of acrylic resin, epoxy resin, phenolic resin, polyamides resin, polyimides resin, unsaturated polyesters resin, poly-phenylene ethers resin, poly-phenylene sulfides resin, and benzocyclobutene (BCB). However, the disclosure is not limited thereto, and the second overcoat layer OC2 of the second bank BNK2 may include various kinds of inorganic insulating materials, including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). In an example, the second overcoat layer OC2 of the second bank BNK2 may include a same material as the first overcoat layer OC1 of the second bank BNK2, but the disclosure is not limited thereto.

In some embodiments, the second overcoat layers OC2 of the first bank BNK1 and the second bank BNK2 may be formed of a same material. In an example, the second overcoat layers OC2 of the first bank BNK1 and the second bank BNK2 may be simultaneously formed through a same process, but the disclosure is not limited thereto.

In an embodiment, a thickness TB1 of the first bank BNK1 in the third direction DR3 may be different from a thickness TB2 of the second bank BNK2 in the third direction DR3. In an example, the thickness TB1 of the first bank BNK1 in the third direction DR3 may be greater than the thickness TB2 of the second bank BNK2 in the third direction DR3. The thickness TB1 of the first bank BNK1 in the third direction DR3 may mean a thickness from a top surface of the substrate SUB to a top surface of the first bank BNK1. The thickness TB2 of the second bank BNK2 in the third direction DR3 may mean a thickness from the top surface of the substrate SUB to a top surface of the second bank BNK2.

Referring to FIG. 7, an optical layer OPL may be disposed in the transmission area TA. For example, the transmission area TA may be surrounded by the above-described bank BNK (e.g., refer to FIG. 6), and the optical layer OPL may be provided in a space surrounded by the bank BNK (e.g., refer to FIG. 6). For example, the first bank BNK1 and the second bank BNK2 (e.g., refer to FIG. 6), which are described above, may correspond to a dam structure for providing the optical layer OPL, and the optical layer OPL may be supplied between the first bank BNK1 and the second bank BNK2 (e.g., refer to FIG. 6) through an inkjet printing process or the like.

The optical layer OPL may have a refractive index relatively lower than that of the substrate SUB. For example, the refractive index of the substrate SUB may be in a range of about 1.5 to about 2.0, and the refractive index of the optical layer OPL may be in a range of about 1.1 to about 1.3. As described above, in case that the optical layer OPL is formed as a low refractive layer, the transmittance (e.g., light transmittance) of the transmission area TA may be improved. However, the disclosure is not limited thereto, and the refractive index of the optical layer OPL may be variously changed within a range in which the transmittance (e.g., light transmittance) of the transmission area TA may be improved.

In case that the optical layer OPL is formed between banks BNK (e.g., refer to FIG. 6), a step difference caused by the emission area EA and/or the line area LA may be minimized. For example, in case that the thickness of the first bank BNK1 of the emission area EA in the third direction DR3 and/or the thickness of the second bank BNK2 of the line area LA in the third direction DR3 is about 10 μm or more, adhesion of a film or the like, which is required according to specifications of the display panel PNL (e.g., refer to FIG. 3), may be deteriorated or the adhesion itself may be impossible, due to a step difference of the transmission area TA, and the emission area EA and/or the line area LA. In other embodiments, the step difference between the transmission area TA and the emission area EA and/or between the transmission area TA and the line area LA is increased, and the film of the display panel PNL (e.g., refer to FIG. 3) may be separated. Thus, the optical layer OPL may be provided between the banks BNK (e.g., adjacent ones of banks BNK of FIG. 6), and the step difference (or thickness or height difference) of the transmission area TA, and the emission area EA and/or the line area LA may be planarized. For example, the step difference between the transmission area TA and the emission area EA and/or between the transmission area TA and the line area LA may be planarized (or minimized). Thus, a display device may be suitable for various specifications. Therefore, a difference (e.g., step difference TBO of first bank BNK1 and optical layer OPL) between the thickness TB1 of the first bank BNK1 in the third direction DR3 and a thickness TO of the optical layer OPL in the third direction DR3 may be about 1 μm or less. However, the disclosure is not limited thereto, and the step difference TBO of the first bank BNK1 and the optical layer OPL may be variously changed within a range in which the film adhesion of the display panel PNL (e.g., refer to FIG. 3) may be ensured.

In some embodiments, the optical layer OPL may include a base resin and hollow particles dispersed in the base resin. The hollow particle may include a hollow silica particle. In other embodiments, the hollow particle may be a pore formed by porogen, but the disclosure is not limited thereto. The optical layer OPL may include at least one of a zinc oxide (ZnO) particle, a titanium dioxide (TiO₂) particle, and a nano silicate particle, but the disclosure is not limited thereto.

FIG. 8 illustrates a light emitting layer EL of an emission area EA (i.e., sub-pixel PXL) and a circuit layer CL of a line area LA. The first transistor T1 (e.g., refer to FIG. 4) of various circuit elements constituting the pixel circuit PXC (e.g., refer to FIG. 4) is illustrated in FIG. 8. In case that the first to third transistors T1, T2, and T3 (e.g., refer to FIG. 4) are designated without being distinguished from each other, each of the first to third transistors T1, T2, and T3 (e.g., refer to FIG. 4) is inclusively referred to as a “transistor T.” The structure of transistors T and/or the positions of the transistors T for each layer are/is not limited to the embodiment shown in FIG. 8, and may be variously changed in some embodiments.

Referring to FIG. 8, the light emitting layer EL of the sub-pixel PXL in accordance with the embodiment of the disclosure may include circuit elements including transistors T disposed on a substrate SUB. First and second electrodes ELT1 and ELT2 (also, referred to as “alignment electrodes”), light emitting elements LD, and/or first and second connection electrodes CNE1 and CNE2, which constitute a light emitting part LSU (e.g., refer to FIG. 4), may be disposed above the circuit elements. Hereinafter, in case that the first and second electrodes ELT1 and ELT2 are inclusively designated or in case that at least one of the first and second electrodes ELT1 and ELT2 is arbitrarily designated, the corresponding electrodes or the corresponding electrode are referred to as “electrodes ELT” or an “electrode ELT.” In case that the first and second connection electrodes CNE1 and CNE2 are inclusively designated or in case that at least one of the first and second connection electrodes CNE1 and CNE2 is arbitrarily designated, the corresponding electrodes or the corresponding electrode are referred to as “connection electrodes CNE” or a “connection electrode CNE.”

A first conductive layer C1 may be disposed on the substrate SUB. The first conductive layer C1 may include a lower conductive layer BML of the transistor T and a first power conductive layer PL2a. The lower conductive layer BML and the first power conductive layer PL2a may be disposed in a same layer. For example, the lower conductive layer BML and the first power conductive layer PL2a may be simultaneously formed through a same process, but the disclosure is not limited thereto. The first power conductive layer PL2a may constitute the second power line PL2 (e.g., refer to FIG. 4) or the like.

The first conductive layer C1 may be formed as a single layer or a multi-layer, which is made of at least one of molybdenum (Mo), copper (Cu), aluminum (Al), chromium (Cr), gold (Au), titanium (Ti), nickel (Ni), neodymium (Nd), and indium tin oxide (ITO). For example, the first conductive layer C1 may include an alloy of the above-described materials.

A buffer layer BFL may be disposed over the first conductive layer C1. The buffer layer BFL may prevent an impurity from being diffused into each circuit element (e.g., transistor T, or the like). The buffer layer BFL may be configured as a single layer, but be configured as a multi-layer including at least two layers. In case that the buffer layer BFL is formed as the multi-layer, the layers may be formed of a same material or be formed of different materials from each other.

A semiconductor pattern SCP may be disposed on the buffer layer BFL. In an example, the semiconductor pattern SCP may include a first region in contact with a first transistor electrode TE1, a second region in contact with a second transistor electrode TE2, and a channel region located between the first and second regions. In some embodiments, one of the first and second regions may be a source region, and another of first and second regions may be a drain region.

In some embodiments, the semiconductor pattern SCP may be made of poly-silicon, amorphous silicon, an oxide semiconductor, or the like. The channel region of the semiconductor pattern SCP may be a semiconductor pattern undoped with an impurity, and may be an intrinsic semiconductor. Each of the first and second regions of the semiconductor pattern SCP may be a semiconductor pattern doped with an impurity. For example, the first and second regions of the semiconductor pattern SCP may be semiconductor patterns doped with different impurities from each other.

A gate insulating layer GI may be disposed on the buffer layer BFL and the semiconductor pattern SCP. In an example, the gate insulating layer GI may be disposed between the semiconductor pattern SCP and a gate electrode GE of the transistor T. The gate insulating layer GI may be disposed between the buffer layer BFL and a second power conductive layer PL2b. The gate insulating layer GI may be configured as a single layer or a multi-layer, and include various kinds of inorganic insulating materials, including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

A second conductive layer C2 may be disposed on the gate insulating layer GI. The second conductive layer C2 may include the gate electrode GE of the transistor T and the second power conductive layer PL2b. The gate electrode GE and the second power conductive layer PL2b may be disposed in a same layer. For example, the gate electrode GE and the second power conductive layer PL2b may be simultaneously formed through a same process, but the disclosure is not limited thereto. The gate electrode GE may be disposed on the gate insulating layer GI, and overlap the semiconductor pattern SCP in the third direction DR3. The second power conductive layer PL2b may be disposed on the gate insulating layer GI, and overlap the first power conductive layer PL2a in the third direction DR3. The second power conductive layer PL2b and the first power conductive layer PL2a may constitute the second power line PL2 (e.g., refer to FIG. 4) or the like.

The second conductive layer C2 may be formed as a single layer or a multi-layer, which is made of at least one of titanium (Ti), copper (Cu), indium tin oxide ITO, molybdenum (Mo), chromium (Cr), gold (Au), nickel (Ni), and neodymium. For example, the second conductive layer C2 may include an alloy of the above-described materials. For example, the second conductive layer C2 may be formed as a multi-layer in which titanium (Ti), copper (Cu), and/or indium tin oxide (ITO) are sequentially or repeatedly stacked.

An interlayer insulating layer ILD may be disposed over the second conductive layer C2. In an example, the interlayer insulating layer ILD may be disposed between the gate electrode GE and the first and second transistor electrodes TE1 and TE2. The interlayer insulating layer ILD may be disposed between the second power conductive layer PL2b and a third power conductive layer PL2c.

The interlayer insulating layer ILD may be configured as a single layer or a multi-layer, and include various kinds of inorganic insulating materials, including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

A third conductive layer C3 may be disposed on the interlayer insulating layer ILD. The third conductive layer C3 may include the first and second transistor electrodes TE1 and TE2 of the transistor T and the third power conductive layer PL2c. The first and second transistor electrodes TE1 and TE2 and the third power conductive layer PL2c may be disposed in a same layer. For example, the first and second transistor electrodes TE1 and TE2 and the third power conductive layer PL2c may be simultaneously formed through a same process, but the disclosure is not limited thereto.

The first and second transistor electrodes TE1 and TE2 may overlap the semiconductor pattern SCP in the third direction DR3. The first and second transistor electrodes TE1 and TE2 may be electrically connected to the semiconductor pattern SCP. For example, the first transistor electrode TE1 may be electrically connected to the first region of the semiconductor pattern SCP through a contact hole penetrating the interlayer insulating layer ILD. The second transistor electrode TE2 may be electrically connected to the second region of the semiconductor pattern SCP through a contact hole penetrating the interlayer insulating layer ILD. The second transistor electrode TE2 may be electrically connected to the lower conductive layer BML, through a contact hole penetrating the interlayer insulating layer ILD and the buffer layer BFL. In some embodiments, any one of the first and second transistor electrodes TE1 and TE2 may be a source electrode, and another of the first and second transistor electrodes TE1 and TE2 may be a drain electrode.

The third power conductive layer PL2c may overlap the first power conductive layer PL2a and/or the second power conductive layer PL2b in the third direction DR3. The third power conductive layer PL2c may be electrically connected to the first power conductive layer PL2a and/or the second power conductive layer PL2b. For example, the third power conductive layer PL2c may be electrically connected to the first power conductive layer PL2a through a contact hole penetrating the interlayer insulating layer ILD and the buffer layer BFL. The third power conductive layer PL2c may be electrically connected to the second power conductive layer PL2b through a contact hole penetrating the interlayer insulating layer ILD. The third power conductive layer PL2c and the first power conductive layer PL2a and/or the second power conductive layer PL2b may constitute the second power line PL2 (e.g., refer to FIG. 4) or the like.

The third conductive layer C3 may be formed as a single layer or a multi-layer, which is made of at least one of aluminum (Al), molybdenum (Mo), chromium (Cr), gold (Au), titanium (Ti), nickel (Ni), neodymium (Nd), and indium tin oxide (ITO). For example, the third conductive layer C3 may include an alloy of the above-described materials.

A protective layer PSV may be disposed over the third conductive layer C3. The protective layer PSV may be configured as a single layer or a multi-layer, and include various kinds of inorganic insulating materials, including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

A via layer VIA may be disposed on the protective layer PSV. The via layer VIA may be made of an organic material to planarize a lower step difference. For example, the via layer VIA may include at least one organic material of acryl resin, epoxy resin, phenolic resin, polyamides resin, polyimides resin, unsaturated polyesters resin, poly-phenylene ethers resin, poly-phenylene sulfides resin, and benzocyclobutene (BCB). However, the disclosure is not limited thereto, and the via layer VIA may include various kinds of inorganic insulating materials, including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

First bank patterns BNP1 may be disposed on the via layer VIA. The first bank patterns BNP1 may have various shapes in some embodiments. In an embodiment, the first bank patterns BNP1 may have a shape protruding in the third direction DR3 on the substrate SUB. The first bank patterns BNP1 may have an inclined surface inclined at an angle with respect to the substrate SUB. However, the disclosure is not limited thereto, and the first bank patterns BNP1 may have a sidewall with a curved shape, a stepped shape, or the like. In an example, the first bank patterns BNP1 may have a cross-section with a semicircular shape, a semi-elliptical shape, or the like.

Electrodes and insulating layers, which are disposed on a top of the first bank patterns BNP1, may have a shape corresponding to the first bank patterns BNP1. In an example, the first and second electrodes ELT1 and ELT2 disposed over the first bank patterns BNP1 may include an inclined surface or a curved surface, which has a shape corresponding to that of the first bank patterns BNP1. Accordingly, the first bank patterns BNP1 and the first and second electrodes ELT1 and ELT2 may serve as or be implemented with, for example, a reflective member which guides light emitted from the light emitting elements LD (e.g., refer to FIG. 4) in a front direction (i.e., third direction DR3) of the sub-pixel PXL. Thus, the light emission efficiency of the display panel PNL (e.g., refer to FIG. 3) may be improved.

The first bank patterns BNP1 may include at least one organic material and/or at least one inorganic material. In an example, the first bank patterns BNP1 may include at least one organic material of acryl resin, epoxy resin, phenolic resin, polyamides resin, polyimides resin, unsaturated polyesters resin, poly-phenylene ethers resin, poly-phenylene sulfides resin, and benzocyclobutene (BCB). However, the disclosure is not limited thereto, and the first bank patterns BNP1 may include various kinds of inorganic insulating materials, including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

A fourth conductive layer C4 may be disposed on the via layer VIA and the first bank patterns BNP1. The fourth conductive layer C4 may include the first and second electrodes ELT1 and ELT2. The first and second electrodes ELT1 and ELT2 may be spaced apart from each other in the sub-pixel PXL in a plan view. The first and second electrodes ELT1 and ELT2 may be disposed in a same layer. For example, the first and second electrodes ELT1 and ELT2 may be simultaneously formed through a same process, but the disclosure is not limited thereto.

The first electrode ELT1 may be electrically connected to the first transistor electrode TE1 of the transistor T through a contact hole penetrating the via layer VIA and the protective layer PSV. The second electrode ELT2 may be electrically connected to the third power conductive layer PL2c through a contact hole penetrating the via layer VIA and the protective layer PSV.

The first and second electrodes ELT1 and ELT2 may be supplied with an alignment signal in a process of aligning the light emitting elements LD (e.g., refer to FIG. 4). Accordingly, an electric field may be formed between the first and second electrodes ELT1 and ELT2, and the light emitting elements LD (e.g., refer to FIG. 4) provided in each sub-pixel PXL may be aligned between the first and second electrodes ELT1 and ELT2.

The fourth conductive layer C4 may include at least one conductive material. In an example, the fourth conductive layer C4 may include at least one metal or any alloy thereof, at least one conductive oxide, at least one conductive material, or the like. The metal or the alloy of the fourth conductive layer C4 may include at least one of silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), and copper (Cu). The conductive oxide of the fourth conductive layer C4 may include at least one of Indium Tin Oxide (ITO), Indium Zinc Oxide (IZO), Indium Tin Zinc Oxide (ITZO), Zinc Oxide (ZnO), Aluminum doped Zinc Oxide (AZO), Gallium doped Zinc Oxide (GZO), Zinc Tin Oxide (ZTO), Gallium Tin Oxide (GTO), and Fluorine doped Tin Oxide (FTO). The conductive material of the fourth conductive layer C4 may include conductive polymers such as PEDOT. However, the disclosure is not limited thereto.

A first insulating layer INS1 may be disposed over the fourth conductive layer C4. The first insulating layer INS1 may be configured as a single layer or a multi-layer, and include various kinds of inorganic insulating materials, including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

A second bank pattern BNP2 may be disposed on the first insulating layer INS1. The second bank pattern BNP2 may form a dam structure which defines an emission area in which light emitting elements LD (e.g., refer to FIG. 4) are supplied in a process of supplying the light emitting elements LD (e.g., refer to FIG. 4) to each of the sub-pixels PXL. For example, a desired kind and/or amount of light emitting element ink may be supplied to an area defined by the second bank pattern BNP2.

The second bank pattern BNP2 may include at least one organic material of acryl resin, epoxy resin, phenolic resin, polyamides resin, polyimides resin, unsaturated polyesters resin, poly-phenylene ethers resin, poly-phenylene sulfides resin, and benzocyclobutene (BCB). However, the disclosure is not limited thereto, and the second bank pattern BNP2 may include various kinds of inorganic insulating materials, including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

In some embodiments, the second bank pattern BNP2 may include at least one light blocking material and/or at least one reflective material. Accordingly, light leakage between adjacent sub-pixels PXL may be prevented. For example, the second bank pattern BNP2 may include at least one black matrix material and/or at least one color filter material. In an example, the second bank pattern BNP2 may be formed as a black opaque pattern capable of blocking transmission of light. In an embodiment, a reflective layer or the like may be formed on a surface (e.g., sidewall) of the second bank pattern BNP2 to increase a light efficiency of each sub-pixel PXL.

The light emitting elements LD (e.g., refer to FIG. 4) may be disposed on the first insulating layer INS1. The light emitting elements LD may be disposed between the first and second electrodes ELT1 and ELT2 on the first insulating layer INS1. The light emitting elements LD may be prepared in a form in which the light emitting elements LD are dispersed in a light emitting element ink, and supplied to each of the sub-pixels PXL through an inkjet printing process, or the like. In an example, the light emitting elements LD may be dispersed in a volatile solvent to be provided to each sub-pixel PXL. Subsequently, in case that an alignment signal is supplied through the first and second electrodes ELT1 and ELT2, the light emitting elements LD may be aligned between the first and second electrodes ELT1 and ELT2, while an electric field is formed between the first and second electrodes ELT1 and ELT2. After the light emitting elements LD are aligned, the solvent may be volatilized or removed through other processes, and the light emitting elements LD may be stably arranged between the first and second electrodes ELT1 and ELT2.

A second insulating layer INS2 may be disposed on the first insulating layer INS1 and the light emitting elements LD (e.g., refer to FIG. 4). For example, the second insulating layer INS2 may be partially provided on the first insulating layer INS1 and the light emitting elements LD, and expose first and second end portions EP1 and EP2 of the light emitting elements LD. In case that the second insulating layer INS2 is formed on the light emitting elements LD after the light emitting elements LD are aligned (e.g., completely aligned), the light emitting elements LD may be prevented from being separated from a position at which the light emitting elements LD are aligned. Further, the second insulating layer INS2 may be formed on the light emitting elements LD, and the first and second connection electrodes CNE1 and CNE2 which is described below may be stably separated from each other.

The second insulating layer INS2 may be configured as a single layer or a multi-layer, and include various kinds of inorganic insulating materials, including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The first and second connection electrodes CNE1 and CNE2 may be respectively disposed on the first and second end portions EP1 and EP2 of the light emitting elements LD (e.g., refer to FIG. 4), which are exposed by the second insulating layer INS2. The first connection electrode CNE1 may be disposed (e.g., directly disposed) on the first end portions EP1 of the light emitting elements LD, and contact the first end portions EP1 of the light emitting elements LD. The first connection electrode CNE1 may be electrically connected to the first electrode ELT1 through a contact hole penetrating the second insulating layer INS2 and the first insulating layer INS1. The second connection electrode CNE2 may be electrically connected to the second electrode ELT2 through a contact hole penetrating the second insulating layer INS2 and the first insulating layer INS1.

Referring to FIG. 8, the first and second connection electrodes CNE1 and CNE2 may be disposed in a same layer. In an example, the first and second connection electrodes CNE1 and CNE2 may constitute a fifth conductive layer C5. The first and second connection electrodes CNE1 and CNE2 may be simultaneously formed through a same process, but the disclosure is not limited thereto.

Referring to FIG. 9, the first and second connection electrodes CNE1 and CNE2 may be disposed in different layers from each other. For example, the first connection electrode CNE1 may constitute a fifth conductive layer C5, and the second connection electrode CNE2 may constitute a sixth conductive layer C6. A third insulating layer INS3 may be further disposed between the fifth conductive layer C5 and the sixth conductive layer C6. The third insulating layer INS3 may cover (or overlap, e.g., in a plan view) the first connection electrode CNE1 constituting the fifth conductive layer C5, and may expose the second end portions EP2 of the light emitting elements LD (e.g., refer to FIG. 4). The second connection electrode CNE2 constituting the sixth conductive layer C6 may be disposed on the second end portions EP2 of the light emitting elements LD, which are exposed by the third insulating layer INS3. As described above, in case that the third insulating layer INS3 is disposed between the first and second connection electrodes CNE1 and CNE2 constituting different conductive layers from each other, the first and second connection electrodes CNE1 and CNE2 may be stably separated from each other by the third insulating layer INS3, and the electrical stability between the first and second end portions EP1 and EP2 of the light emitting elements LD may be ensured.

The fifth conductive layer C5 and/or the sixth conductive layer C6 may be configured with various transparent conductive materials. In an example, the fifth conductive layer C5 and/or the sixth conductive layer C6 may include at least one of various transparent conductive materials including at least one of Indium Tin Oxide (ITO), Indium Zinc Oxide (IZO), Indium Tin Zinc Oxide (ITZO), Aluminum doped Zinc Oxide (AZO), Gallium doped Zinc Oxide (GZO), Zinc Tin Oxide (ZTO), and Gallium Tin Oxide (GTO), and be implemented substantially transparently or translucently to satisfy a transmittance (e.g., light transmittance). Accordingly, light emitted from the first and second end portions EP1 and EP2 of the light emitting elements LD (e.g., refer to FIG. 4) may pass through the first and second connection electrodes CNE1 and CNE2 and be emitted to the outside of the display panel PNL (e.g., refer to FIG. 3).

The third insulating layer INS3 may be configured as a single layer or a multi-layer, and include various kinds of inorganic insulating materials, including at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The line area LA in accordance with the embodiment of the disclosure may include signal lines SL1, SL2, and SL3 disposed on the substrate SUB. The signal lines SL1, SL2, and SL3 may constitute a power line, a data line, a scan line, and the like, which are electrically connected to an adjacent emission area EA.

The signal lines SL1, SL2, and SL3 may include first to third signal lines SL1, SL2, and SL3 disposed in different layers from each other. The first signal line SL1 may be disposed on the substrate SUB. In an example, the first signal line SL1 may be formed as the above-described first conductive layer C1. The second signal line SL2 may be disposed on the buffer layer BFL. In an example, the second signal line SL2 may be formed as the above-described second conductive layer C2. The third signal line SL3 may be disposed on the interlayer insulating layer ILD. In an example, the third signal line SL3 may be formed as the above-described third conductive layer C3.

Although the first bank patterns BNP1, the electrodes ELT1 and ELT2, the second bank patterns BNP2, and/or the connection electrodes CNE, which are described above with reference to FIG. 8, are omitted in the line area LA, the disclosure is not limited thereto. In an example, the electrodes ELT1 and ELT2 or the connection electrodes CNE1 and CNE2 may be partially disposed in the line area LA.

In accordance with the above-described embodiment, the bank BNK (e.g., refer to FIG. 6) may be formed in the emission area EA and the line area LA, and the optical layer OPL may be provided in the transmission area TA surrounded by the bank BNK (e.g., refer to FIG. 6). Thus, the transmittance (e.g., light transmittance) of the transmission area TA may be improved, and simultaneously, the step difference caused by the emission area EA and/or the line area LA may be minimized.

Hereinafter, another embodiment is described below. In the following embodiment, components identical to those described above are designated by like reference numerals, and overlapping descriptions will be omitted or simplified.

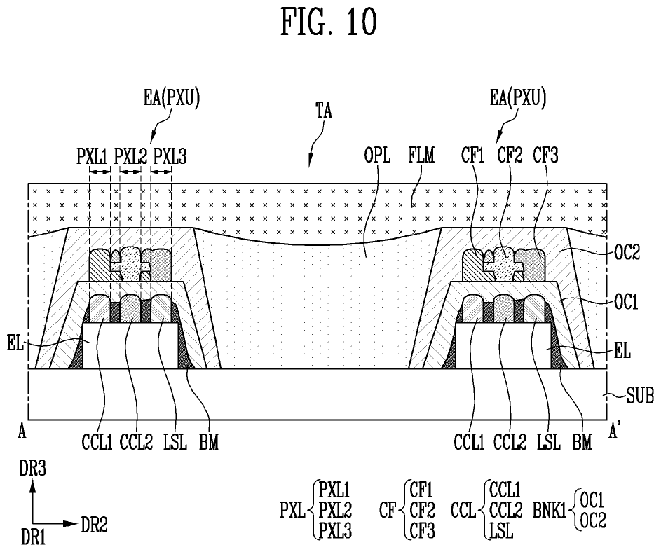

FIG. 10 is a schematic cross-sectional view illustrating an emission area and a transmission area in accordance with another embodiment of the disclosure. FIG. 10 may be a cross-section corresponding to the line A-A′ shown in FIG. 5.

Referring to FIG. 10, the emission area and the transmission area of this embodiment is distinguished from the embodiment shown in FIGS. 1 to 9, at least in that a light transmissive film FLM is disposed on the bank BNK (e.g., refer to FIG. 6).

For example, a light transmissive film FLM may be disposed on a second overcoat layer OC2 of a bank BNK (e.g., refer to FIG. 6). In an example, the light transmissive film FLM may be attached onto a surface of the second overcoat layer OC2. The light transmissive film FLM may be attached onto a surface of an optical layer OPL. As described above, in case that the optical layer OPL is provided between the banks BNK, a step difference of the transmission area TA, and the emission area EA and/or a line area LA (e.g., refer to FIG. 8) may be planarized, and the light transmissive film FLM may be readily attached, which has been described above. For example, the step difference between the transmission area TA and the emission area EA and/or between the transmission area TA and the line area LA (e.g., refer to FIG. 8) may be planarized, and the light transmissive film FLM may be readily attached.

The light transmissive film FLM may be provided throughout an entire surface of a substrate SUB. The light transmissive film FLM may be attached to an entire surface of the display panel PNL (e.g., refer to FIG. 3), to protect the entire surface of the display panel PNL (e.g., refer to FIG. 3) and/or to minimize reflection of external light incident onto the display panel PNL (e.g., refer to FIG. 3). For example, the light transmissive film FLM may be at least one of a polyethyleneterephthalate (PET) film a low reflective film, a polarizing film, and a transmittance controllable film, but the disclosure is not limited thereto. In some embodiments, the light transmissive film FLM may further include an adhesive layer attached to the second overcoat layer OC2 of the bank BNK and/or the optical layer OPL. The adhesive layer may include at least one of an optically clear adhesive (OCA), an optically transparent adhesive resin (OCR), a pressure sensitive adhesive (PSA), and an ultraviolet curing adhesive, but the disclosure is not limited thereto.

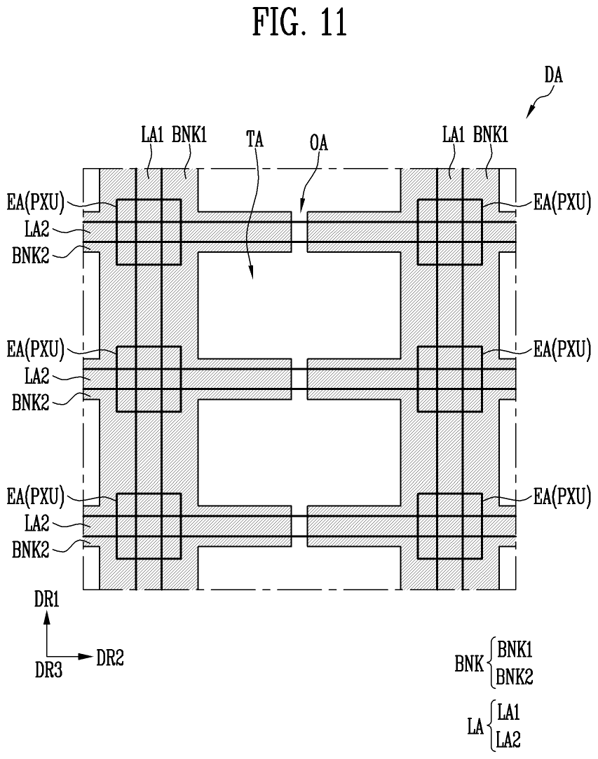

FIGS. 11 to 14 are schematic plan views illustrating a display area in accordance with still another embodiment of the disclosure.

Referring to FIGS. 11 to 14, the display area of this embodiment is distinguished from the embodiment shown in FIGS. 1 to 9, at least in that a bank BNK includes an open area OA.

For example, referring to FIG. 11, a second bank BNK2 may include an open area which is partially removed. The open area OA may connect adjacent ones of transmission areas TA defined by the bank BNK. Although an optical layer OPL (e.g., refer to FIG. 7) is not provided in some transmission areas TA, the optical layer OPL provided in an adjacent transmission area TA may be provided in the open area OA, and moved to the transmission area TA in which the optical layer OPL is not provided through the open area OA. For example, a material for forming the optical layer OPL, which is provided in the transmission area TA, may be transported to the adjacent transmission area TA through the open area OA. Thus, the display device may be free from an inkjet equipment capacity or resolution limitation.

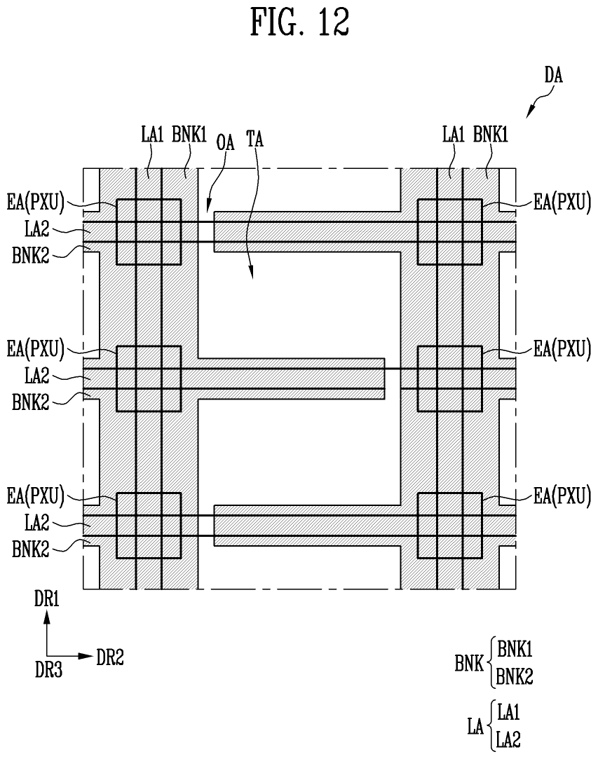

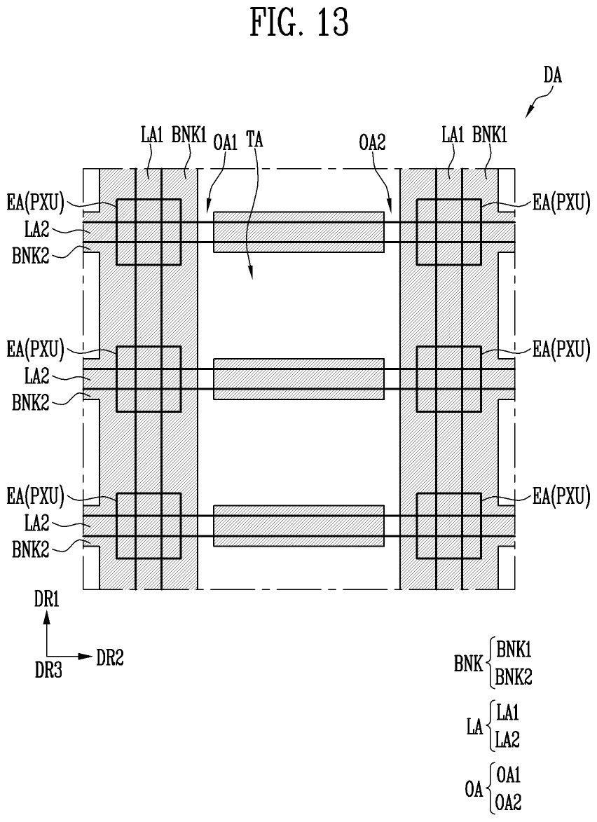

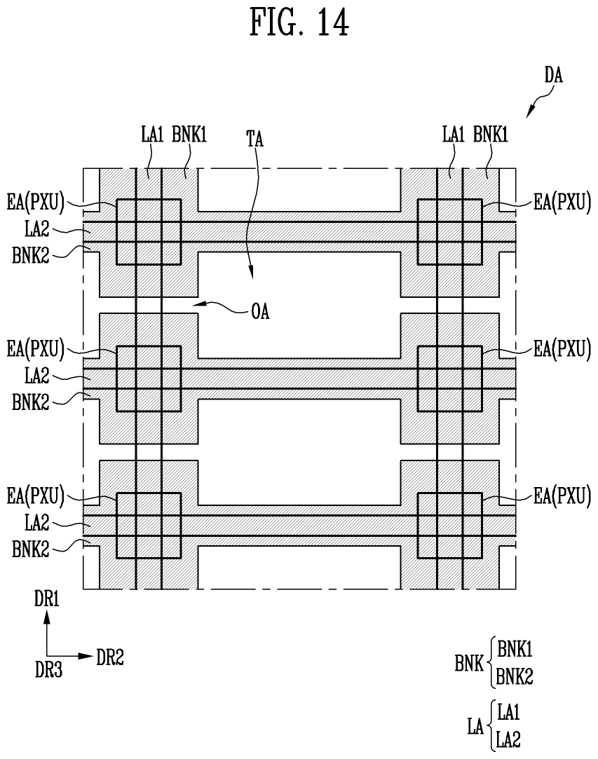

A position of the open area OA of the second bank BNK2 may be variously changed. For example, as shown in FIG. 11, the second bank BNK2 disposed between adjacent first banks BNK1 may be partially removed, and the open area OA may be formed between the adjacent first banks BNK1. In other embodiments, as shown in FIG. 12, the second bank BNK2 may be partially removed at a spot adjacent to the first bank BNK1, and an open area OA may be formed at the spot adjacent to the first bank BNK1. In other embodiments, the second bank BNK2 may include multiple open areas OA. In an example, as shown in FIG. 13, the open area OA may include a first open area OA1 and a second open area OA2. The first open area OA1 may be formed at a spot adjacent to the first bank BNK1 disposed at a side of the transmission area TA. The second open area OA2 may be formed at a spot adjacent to the first bank BNK1 disposed at another side of the transmission area TA. Although the open area OA of FIGS. 11 to 13 is formed in the second bank BNK2, the disclosure is not limited thereto. For example, as shown in FIG. 14, the first bank BNK1 may include an open area OA in which the first bank BNK1 is partially removed. For example, the positions, shape, number, and the like of open areas OA of the bank BNK may be variously changed within a range in which the optical layer OPL may be moved between the transmission areas TA. For example, a material for forming the optical layer OPL may be moved between adjacent ones of the transmission areas TA through the open areas OA.

In accordance with the disclosure, a bank may be formed in an emission area and a line area, and an optical layer may be provided in a transmission area surrounded by the bank. Thus, the transmittance (e.g., light transmittance) of the transmission area may be improved, and simultaneously, a step difference caused by the emission area and/or the line area may be minimized. Accordingly, the adhesion of a film, which is required according to specifications of the display panel, may be improved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
an emission area including light emitting elements;
a line area including signal lines electrically connected to the light emitting elements;
a transmission area disposed at a periphery of the emission area and the line area;
a bank disposed in the emission area and the line area; and
an optical layer disposed in a space surrounded by the bank in the transmission area.

2. The display device of claim 1, wherein the bank includes:
a first overcoat layer; and
a second overcoat layer disposed over the first overcoat layer.

3. The display device of claim 2, wherein the emission area further includes a color conversion layer disposed on the light emitting elements.

4. The display device of claim 3, wherein the first overcoat layer is disposed over the color conversion layer.

5. The display device of claim 4, wherein the emission area further includes a color filter layer disposed on the color conversion layer.

6. The display device of claim 5, wherein the second overcoat layer is disposed over the color filter layer.

7. The display device of claim 1, wherein the emission area further includes:
a first electrode electrically connected to first end portions of the light emitting elements; and
a second electrode electrically connected to second end portions of the light emitting elements.

8. The display device of claim 1, wherein a difference between a thickness of the bank and a thickness of the optical layer is about 1 μm or less.

9. The display device of claim 1, wherein an area of the transmission area is greater than at least one of an area of the emission area and an area of the line area.

10. The display device of claim 1, further comprising:
a light transmissive film disposed on the optical layer.

11. A display device comprising:
a first line area extending in a first direction;
a second line area extending in a second direction intersecting the first direction;
an emission area electrically connected to the first line area or the second line area;
a first bank disposed in the emission area and the first line area;
a second bank disposed in the emission area and the second line area; and
an optical layer disposed between the first bank and the second bank.

12. The display device of claim 11, wherein the first bank extends in the first direction.

13. The display device of claim 11, wherein the second bank extends in the second direction.

14. The display device of claim 11, wherein the first bank and the second bank include a same material.

15. The display device of claim 11, wherein at least one of the first bank and the second bank includes an open area.

16. The display device of claim 15, wherein the optical layer is disposed in the open area.

17. The display device of claim 11, wherein the optical layer has a refractive index in a range of about 1.1 to about 1.3.

18. The display device of claim 11, wherein the optical layer includes a hollow particle.

19. The display device of claim 11, wherein a width of the first bank in the second direction is greater than a width of the second bank in the first direction.

20. The display device of claim 11, wherein a thickness of the first bank is greater than a thickness of the second bank.
